(19) United States
(12) Patent Application Publication
(10) Pub. No.: US 2024/0332247 A1
(43) Pub. Date: Oct. 3, 2024

(54) LIGHT EMITTING DEVICE AND METHOD OF MANUFACTURING SAME

(71) Applicant: NICHIA CORPORATION, Anan-shi (JP)

(72) Inventors: Hiroaki KAGEYAMA, Tokushima-shi (JP); Yuka IMADA, Anan-shi (JP); Hiroki HANAOKA, Anan-shi (JP)

(73) Assignee: NICHIA CORPORATION, Anan-shi (JP)

(21) Appl. No.: 18/613,110

(22) Filed: Mar. 22, 2024

(30) Foreign Application Priority Data
Mar. 30, 2023 (JP) 2023-055882
Jul. 18, 2023 (JP) 2023-116943

(51) Int. Cl. H01L 23/00; H01L 21/66; H01L 25/075; H01L 33/40; H01L 33/62

(52) U.S. Cl. CPC H01L 24/80; H01L 22/22; H01L 24/05; H01L 24/08; H01L 24/95; H01L 25/0753; H01L 33/40; H01L 33/62; H01L 2224/05644; H01L 2224/08225; H01L 2224/80052; H01L 2224/80201; H01L 2224/80444; H01L 2224/95; H01L 2924/12041; H01L 2933/0066

(57) ABSTRACT

A method of manufacturing a light emitting device includes preparing a plurality of first elements including first bonding parts and a wiring substrate including a plurality of second bonding parts. The method further includes placing the first elements on the wiring substrate by bonding the first bonding parts and the second bonding parts under first bonding conditions, and bonding the first bonding parts and the second bonding parts under second bonding conditions by placing a buffer sheet on the first elements and applying pressure on the first elements via the buffer sheet towards the wiring substrate. The bonding conducted under the second bonding conditions is performed multiple times.

### CROSS-REFERENCE TO RELATED APPLICATIONS

The present application claims priority under 35 U.S.C. § 119 to Japanese Patent Application No. 2023-055882, filed Mar. 30, 2023, and Japanese Patent Application No. 2023-116943, filed Jul. 18, 2023, the contents of which are hereby incorporated by reference in their entirety.

### BACKGROUND

### 1. Technical Field

The present disclosure relates to a light emitting device and a method of manufacturing the same.

### 2. Description of Related Art

Japanese Patent Publication No. 2020-074005 describes a light emitting device in which a large number of semiconductor elements are arranged on a single wiring substrate. When manufacturing such a light emitting device, bonding a number of semiconductor elements on a wiring substrate all at once increases the production efficiency, but can produce bonding strength variation among the semiconductor elements bonded to the wiring substrate.

### SUMMARY

An embodiment of the present disclosure can advantageously provide a light emitting device and a method of manufacturing the same that can reduce the bonding strength variation among the light emitting elements bonded to the wiring substrate.

A method of manufacturing a light emitting device according to an embodiment of the present disclosure includes: preparing a plurality of first elements and a wiring substrate, the plurality of first elements includes first bonding parts, the wiring substrate includes a plurality of second bonding parts; placing the plurality of first elements on the wiring substrate by bonding the first bonding parts and the second bonding parts under first bonding conditions; and bonding the first bonding parts and the second bonding parts under second bonding conditions by placing a buffer sheet on the plurality of first elements and applying pressure on the plurality of first elements via the buffer sheet towards the wiring substrate. The bonding conducted under the second bonding conditions is performed multiple times.

A light emitting device according to an embodiment of the present disclosure includes a wiring substrate including wires, a plurality of first elements, and a plurality of bonding parts for connecting the plurality of first elements to the wires. A ratio of a standard deviation to an average value of a bonding strength of the plurality of first elements to the wiring substrate is 0.1 or lower.

A light emitting device according to an embodiment of the present disclosure includes a wiring substrate having wires, a plurality of first elements, and a plurality of bonding parts for connecting the plurality of first elements to the wires. In a plan view, a length of a side of each first element of the plurality of first elements is 500 μm to 1500 μm. An average value of a bonding strength of the plurality of first elements to the wiring substrate is 10 kgf or higher.

According to an embodiment of the present disclosure, a light emitting device and a method of manufacturing the same that can reduce bonding strength variation among the elements bonded to the wiring substrate can be provided.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1 is a flowchart of a method of manufacturing a light emitting device according to a first embodiment.

FIG. 2 is a cross-sectional view of a first element in the first embodiment.

FIG. 3 is a plan view of a wiring substrate in the first embodiment.

FIG. 4 is a cross-sectional view taken along line IV-IV in FIG. 3.

FIG. 5 is a cross-sectional view showing a method of manufacturing a light emitting device according to the first embodiment.

FIG. 6 is a cross-sectional view showing the method of manufacturing a light emitting device according to the first embodiment.

FIG. 7 is a cross-sectional view showing the method of manufacturing a light emitting device according to the first embodiment.

FIG. 8 is a cross-sectional view showing the method of manufacturing a light emitting device according to the first embodiment.

FIG. 9 is a cross-sectional view showing the method of manufacturing a light emitting device according to the first embodiment.

FIG. 10 is a cross-sectional view showing the method of manufacturing a light emitting device according to the first embodiment.

FIG. 11 is a cross-sectional view showing the method of manufacturing a light emitting device according to the first embodiment.

FIG. 12 is a cross-sectional view showing the method of manufacturing a light emitting device according to the first embodiment.

FIG. 13 is a cross-sectional view showing the method of manufacturing a light emitting device according to the first embodiment.

FIG. 14 is a plan view of a light emitting device according to the first embodiment.

FIG. 15 is a cross-sectional view taken along line XV-XV in FIG. 14.

FIG. 16 is a cross-sectional view showing a method of manufacturing a light emitting device according to a second embodiment.

FIG. 17 is a plan view of a light emitting module according to a third embodiment.

FIG. 18 is a plan view partially enlarging a first element and a wavelength conversion member in the third embodiment.

FIG. 19 is a diagram of a measuring device for measuring the bonding strength of a test example.

FIG. 20A is a front view of a tool portion of the measuring device used for the test example.

FIG. 20B is a side view of the tool portion of the measuring device shown in FIG. 20A.

FIG. 20C is an enlarged view of the region XXC in FIG. 20B.

FIG. 21 is a cross-sectional view showing a method of measuring the bonding strength of the test example.

FIG. 22 is a graph showing the bonding strength of the example and a comparative example.

### DETAILED DESCRIPTION OF EMBODIMENTS

Certain embodiments of the present disclosure will be explained below with reference to the accompanying drawings. The drawings are schematic and conceptual. As such, the relationship between the thickness and the width of each part, the size ratio of members, and the like are not necessarily identical with those of an actual product. Even when the same portion is shown, the size or ratio might differ depending on the drawing. In the present specification and drawings, similar elements already described using previously referenced drawings will be denoted with the same reference numerals for which detailed description is omitted as appropriate. An end face diagram only showing a cut section might be used as a cross-sectional view.

### First Embodiment

A method of manufacturing a light emitting device according to a first embodiment will be explained below.

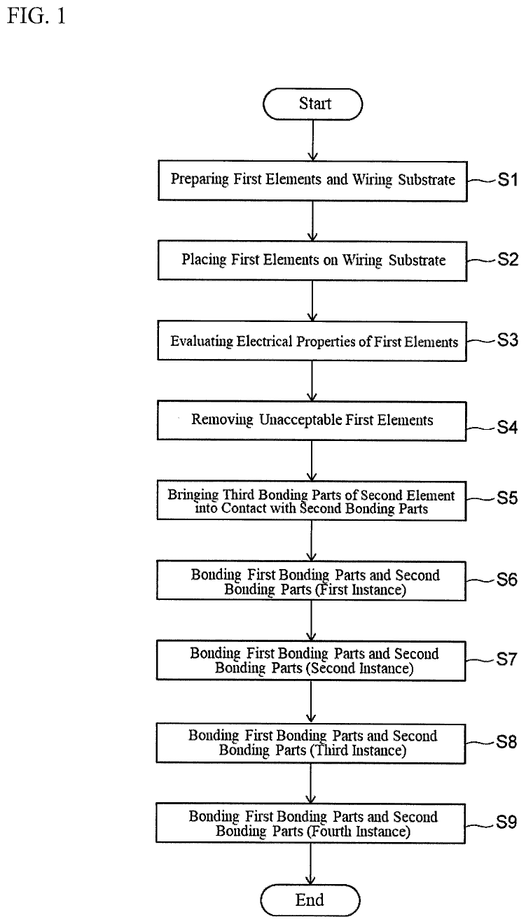

FIG. 1 is a flowchart of a method of manufacturing a light emitting device according to this embodiment.

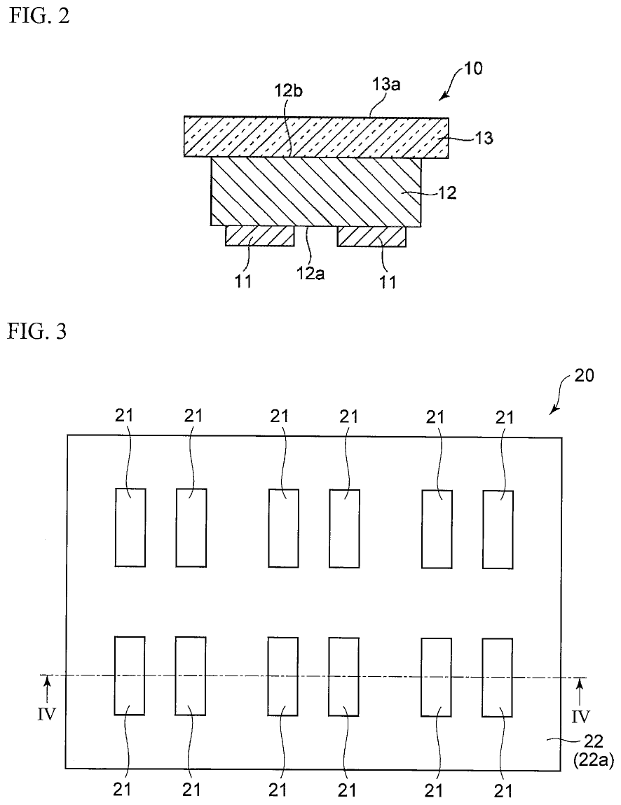

FIG. 2 is a cross-sectional view of a first element in this embodiment.

FIG. 3 is a plan view of a wiring substrate in this embodiment.

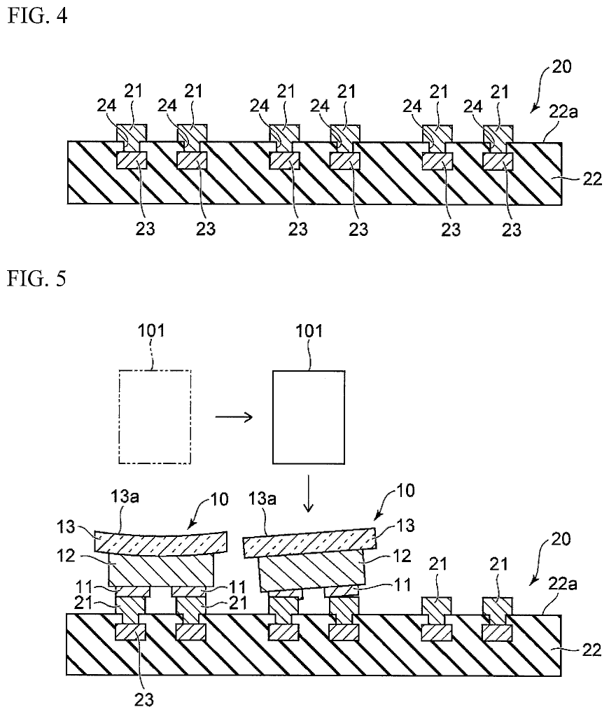

FIG. 4 is a cross-sectional view taken along line IV-IV in FIG. 3.

FIG. 5 to FIG. 13 are cross-sectional views showing the method of manufacturing a light emitting device according to this embodiment.

### Preparing First Elements and Wiring Substrate

In the step S1 in FIG. 1, first elements 10 and a wiring substrate 20 are prepared as shown in FIG. 2 and FIG. 3, for example. Each first element includes first bonding parts 11. The wiring substrate 20 includes second bonding parts 21. First elements 10 can be prepared before or after preparing a wiring substrate 20. The first elements 10 and the wiring substrate 20 can be prepared by manufacturing or through purchase from another source.

A first element 10 will be described first. As shown in FIG. 2, the first element 10 is a light emitting element having a pair of first bonding parts 11, a semiconductor member 12, and a wavelength conversion member 13. It is, for example, a light emitting diode (LED).

In the semiconductor member 12, a p-type semiconductor layer, an active layer, and an n-type semiconductor layer are stacked. The semiconductor member 12 has a first face 12a and a second face 12b. The second face 12b is located opposite the first face 12a. The pair of first bonding parts 11 are disposed on the first face 12a of the semiconductor member 12.

One of the pair of first bonding parts 11 is connected to the p-type semiconductor layer of the semiconductor member 12, and the other is connected to the n-type semiconductor layer of the semiconductor layer. This allows the pair of first bonding parts 11 to function as an anode electrode or cathode electrode of the first element 10. In the present specification, “connection” refers to electrical connection, and “bonding” refers to the state in which both electrical connection and mechanical connection are achieved. The first bonding parts 11 include gold (Au). For example, at least the outermost surfaces of the first bonding parts 11 are made of gold. The first bonding parts 11 are, for example, 0.01 μm to 1 μm in thickness.

The wavelength conversion member 13 is disposed on the second face 12b of the semiconductor member 12. The wavelength conversion member 13 has, for example, a base material made of a light transmissive resin or inorganic material, and a phosphor disposed in the base material. The phosphor is, for example, YAG (yttrium aluminum garnet). When viewed from the second face 12b side, for example, the wavelength conversion member 13 is larger than the semiconductor member 12 and the outline of the wavelength conversion member 13 is positioned outside of the outline of the semiconductor member 12. When viewed from the second face 12b side, the shape of the wavelength conversion member 13 is, for example, a square, each side being 45 μm in length. The wavelength conversion member 13 can be disposed on the second face 12b of the semiconductor member 12 via a light transmissive member such as sapphire.

The face of the wavelength conversion member 13 located opposite the face that is in contact with the semiconductor member 12 is a light emission face 13a. The light emission face 13a parallels the first face 12a and the second face 12b of the semiconductor member 12. Moreover, the light emission face 13a is preferably flat. However, the shapes of the first elements 10 might unavoidably vary. For example, a wavelength conversion member 13 might be warped in which case the light emission face 13a might be curved to have a concave or convex shape.

Supplying power across the pair of first bonding parts 11 allows the semiconductor member 12 to emit blue light, for example. The wavelength conversion member 13 absorbs a portion of the light emitted by the semiconductor member 12 and emits yellow light. This allows the first element 10 to emit white light resulting from mixing blue light and yellow light.

The wiring substrate 20 will be described next. As shown in FIG. 3 and FIG. 4, the wiring substrate 20 includes an insulation base 22 and a number of second bonding parts 21. The second bonding parts 21 are arranged on the base 22. The second bonding parts 21 include gold. For example, at least the outermost surface of each second bonding part 21 is made of gold.

The second bonding parts 21 are arranged in a matrix on the upper face 22a of the base 22, for example. However, the layout of the second bonding parts 21 is not limited to a matrix, and can be any other layout. The second bonding parts 21 are positioned to individually come into contact with the first bonding parts 11 of the first elements 10 when the first faces 12a of the semiconductor members 12 are opposed to the upper face 22a of the base 22 of the wiring substrate 20.

In the example shown in FIG. 3 and FIG. 4, a number of wires 23 are disposed inside the base 22. In the upper face 22a, a number of openings 24 are created in the base 22, and a wire 23 is exposed in each opening 24. The surfaces of each wire 23 that are not exposed in the opening 24 are covered by the base 22. Each second bonding part 21 is disposed on the upper face 22a of the base 22 and in an opening 24. Each second bonding part 21 is connected to a wire 23 at the bottom of an opening 24.

### Placing First Elements on Wiring Substrate

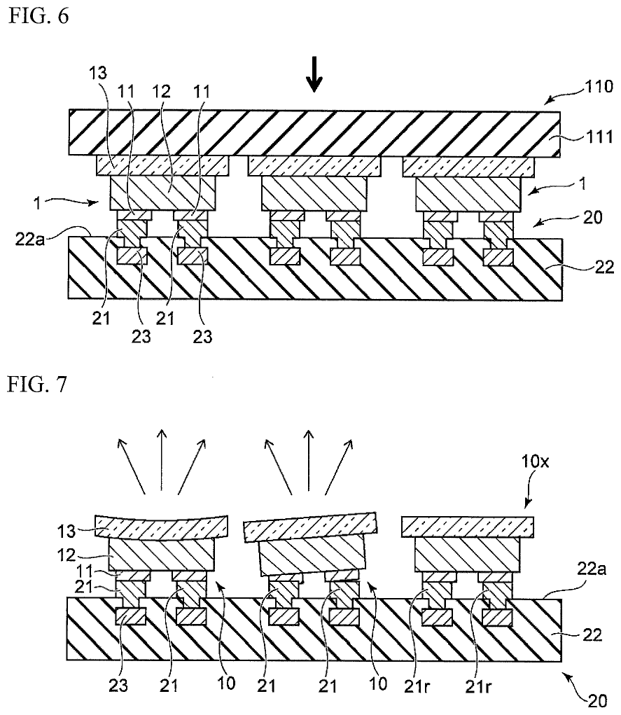

In step S2 in FIG. 1, the first elements 10 are placed on the wiring substrate 20 by bonding the first bonding parts 11 of the first elements 10 to the second bonding parts 21 of the wiring substrate 20 under first bonding conditions as shown in FIG. 5 or FIG. 6, for example.

The first elements 10 can be placed on the wiring substrate 20 one by one. Specifically, as shown in FIG. 5, the first elements 10 are placed on the wiring substrate 20 one by one by using a suction nozzle 101. At this time, the first bonding parts 11 of the first elements 10 which came into contact with the second bonding parts 21 of the wiring substrate 20 are connected thereto under the first bonding conditions. Multiple first elements 10 are placed on a single wiring substrate 20 by repeating the step of placing a first element 10 on the wiring substrate 20 by moving the suction nozzle 101. The distance between two adjacent first elements 10 is set, for example, to 5 μm.

Alternatively, the first elements 10 can be placed on the wiring substrate 20 all at once. Specifically, as shown in FIG. 6, a structure 110 is prepared in which multiple first elements 10 are disposed on a support substrate 111. Then the structure 110 is opposed to a wiring substrate 20, bringing the first bonding parts 11 of the first elements 10 into contact with the second bonding parts 21 to be joined under the first bonding conditions. Then the support substrate 111 is detached from the first elements 10. In this manner, multiple first elements 10 can be placed on a single wiring substrate 20.

The step shown in FIG. 5 or FIG. 6 is conducted such that the heights of the light emission faces 13 of the wavelength conversion members 13 of the first elements 10, i.e., the distances from the upper face 22a of the base 22 of the wiring substrate 20, are uniform among the first elements 10, and the light emission faces 13a parallel the upper face 22a.

In this step, however, unavoidable variation might occur, i.e., there might be variation in the heights of the light emission faces 13a among the first elements 10. Furthermore, some of the light emission faces 13a might become oblique to the upper face 22a. Some of the light emission faces 13a might be warped so as not to be in parallel with the upper face 22a.

In this step, by using the first bonding conditions, the first bonding parts 11 and the second bonding parts 21 are heated, and subjected to a load in the direction to approach one another. For the first bonding conditions, the temperature is preferably set to 80° C. to 200° C., more preferably 100° C. to 150° C., for example, 140° C. The load applied to the first bonding parts 11 and the second bonding parts 21 is preferably set to 10 MPa to 100 MPa, more preferably 10 MPa to 40 MPa. In the first bonding conditions, moreover, the duration of applying a load to the first bonding parts 11 and the second bonding parts 21 is preferably set to 0.1 seconds to 10 seconds, more preferably 0.1 seconds to 1 second, for example, 0.5 seconds. For the first bonding conditions, the application of ultrasonic waves is not preferable.

In this step, a surface of a first bonding part 11 is bonded to a surface of a second bonding part 21 while generally maintaining the pre-bonding shapes of the first bonding part 11 and the second bonding part 21. Bonding the first bonding parts 11 and the second bonding parts 21 under the first bonding conditions can achieve the connection between the first bonding parts 11 and the second bonding parts 21, but the mechanical bonding strength is lower than the bonding strength achieved under the second bonding conditions described later. Hereinbelow, the state achieved under the first bonding conditions will be referred to as “provisionally bonded state.” The first elements 10 are thus placed on the wiring substrate 20.

### Evaluating Electrical Properties of First Elements

Next, in step S3 in FIG. 1, the electrical properties of the first elements 10 provisionally bonded to the wiring substrate 20 are evaluated as shown in FIG. 7, for example.

Specifically, power is supplied to the first elements 10 via the wiring substrate 20 to evaluate the electrical properties of the first elements 10. In the case where the first elements 10 are light emitting elements, the electrical property to be evaluated is, for example, the luminous intensity of the light emitted from the light emitting elements when a predetermined voltage is applied, for example. By evaluating such electrical properties, the first elements 10 bonded to the wiring substrate 20 are categorized into acceptable and unacceptable elements.

For example, the first elements 10 that emitted light of standard luminous intensity or higher are categorized as acceptable elements, and those having luminous intensity under the standard value are categorized as unacceptable elements. Hereinbelow, those determined to be unacceptable will be referred to as “first elements 10x.” The second bonding parts 21 connected to the first elements 10x determined to be unacceptable in evaluating the electrical properties of the first element 10 will be referred to as “second bonding parts 21r.”

Removing First Elements Determined to be Unacceptable from Wiring Substrate

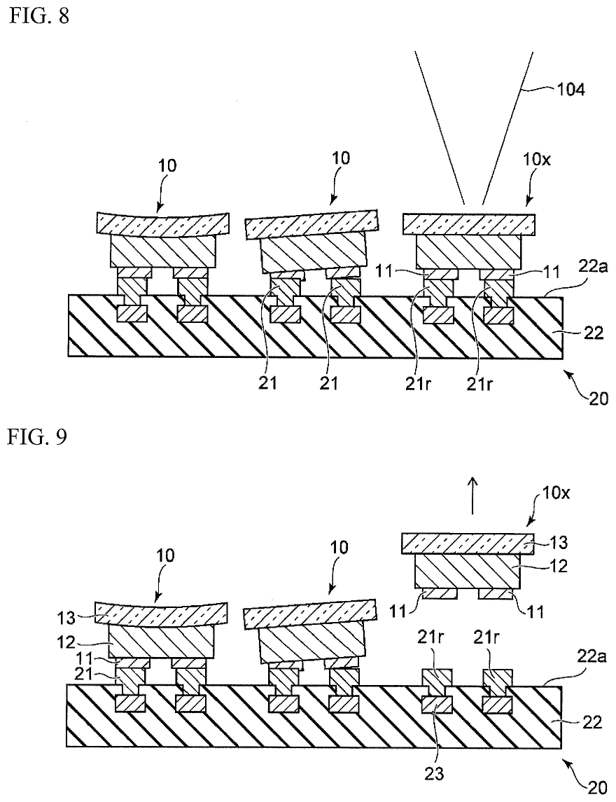

In step S4 in FIG. 1, the first elements 10x determined to be unacceptable in step S3 are removed from the wiring substrate 20 by detaching the first bonding parts 11 of the first elements 10x from the second bonding parts 21r as shown in FIG. 8 and FIG. 9, for example. This step is not conducted if there is no first element 10x determined to be unacceptable in step S3.

In this embodiment, a first element 10x is heated by irradiating a laser beam 104 on the first element 10x, for example. This applies thermal stress to the interfaces between the first bonding parts 11 and the second bonding parts 21r, detaching the first bonding parts 11 of the first element 10x from the second bonding parts 21r. In the case where the first element 10x is a light emitting element which includes a semiconductor member, the laser beam 104 is focused on the upper face of the semiconductor member. This causes the semiconductor member hit by the laser beam 104 to thermally expand, generating thermal stress and detaching the first bonding parts 11 from the second bonding parts 21r.

The method of removing a first element 10x from the wiring substrate 20 is not limited to the method employing a laser beam 104 described above. For example, a first element 10x can be pulled out of the wiring substrate 20 by using a sticky tool. Alternatively, a first element 10x can be removed by using a suctioning device, or blown off with air.

### Bonding Third Bonding Parts of Second Element to Second Bonding Parts

In step S5 in FIG. 1, a second element 15 is prepared. The second element 15 has the same structure as the first element 10, for example. The second element 15 includes, in addition to a semiconductor member 12 and a wavelength conversion member 13, a pair of third bonding parts 16. The third bonding parts 16 include gold. The positions, structures, compositions, and functions of the third bonding parts 16 of a second element 15 are similar to those of the first bonding parts 11 of a first element 10. This step is not conducted if there is no first element 10x determined to be unacceptable in step S3.

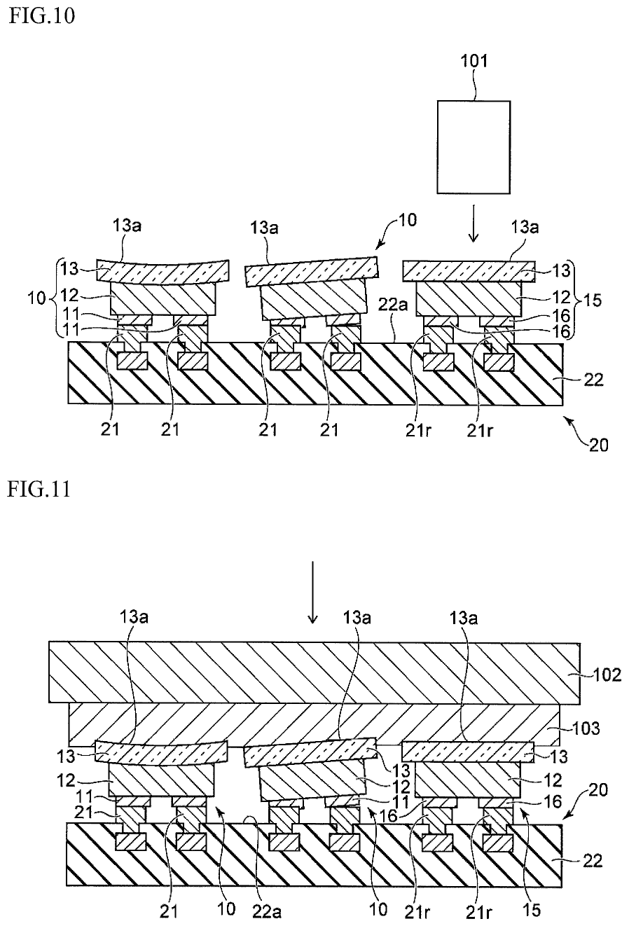

As shown in FIG. 10, for example, a second element 15 is placed in the region of the wiring substrate 20 which used to be occupied by the first element 10x before removal by using a suction nozzle 101. This brings the third bonding parts 16 of the second element 15 into contact with the second bonding parts 21r. The third bonding parts 16 of the second element 15 can be provisionally bonded to the second bonding parts 21r of the wiring substrate 20 under the first bonding conditions. Even in this case, the light emission face 13a of the wavelength conversion member 13 of the second element 15 might be curved, making the light emission face 13a oblique to the upper face 22a and the height of the light emission face 13a of the second element 15 different from the heights of the light emission faces 13a of the first elements 10.

### Bonding First Bonding Parts and Second Bonding Parts Under Second Bonding Conditions

Then in step S6 in FIG. 1, a buffer sheet 103 is placed on the first elements 10 as shown in FIG. 11, for example. If a second element 15 is present, the buffer sheet 103 is placed on the second element 15 as well. The buffer sheet 103 is a plastically deformable sheet, and is a carbon sheet, for example. The thickness of the buffer sheet 103 is preferably set to 0.1 mm to 0.2 mm, for example, more preferably 0.1 mm to 0.15 mm, for example, 0.13 mm.

Then the first elements 10 and the second elements 15 are pressed towards the wiring substrate 20 via the buffer sheet 103 by using a press plate 102. The bonding of the first bonding parts 11 to the second bonding parts 21 and the third bonding parts 16 to the second bonding parts 21r, is conducted under second bonding conditions. The second bonding conditions are those that achieve stronger bonding than that achieved by the first bonding conditions.

In this manner, the first bonding parts 11 and the second bonding parts 21 which have been provisionally bonded are bonded under the second bonding conditions. If a second element 15 is present, the third bonding parts 16 of the newly placed second element 15 are bonded under the second bonding conditions to the second bonding parts 21r which used to be bonded to the first bonding parts 11 of the removed first element 10x.

Hereinbelow, for explanation purposes, unless otherwise specifically noted, the first elements 10 and the second elements 15 are collectively referred to as “first elements 10,” and the first bonding parts 11 and the third bonding parts 16 are collectively referred to as “first bonding parts 11” regardless of whether or not a second element 15 is present.

The second bonding conditions will be explained below.

The load in the second bonding conditions can be set higher than the load in the first bonding conditions. For example, as compared to the load applied to the first bonding parts 11 and the second bonding parts 21 under the first bonding conditions preferably being set to 10 MPa to 100 MPa described earlier, the load applied to the first bonding parts 11 and the second bonding parts 21 under the second bonding conditions is preferably set to 10 MPa to 440 MPa.

Alternatively, the duration of load application under the second conditions can be set longer than the duration under the first conditions. For example, as compared to the duration of applying a load to the first bonding parts 11 and the second bonding parts 21 under the first conditions preferably being set to 0.1 seconds to 10 seconds, the duration of applying a load to the first bonding parts 11 and the second bonding parts 21 under the second conditions is preferably set to 1 minute to 10 minutes.

Alternatively, the temperature in the second bonding conditions can be set higher than the temperature in the first bonding conditions. For example, as compared to the temperature under the first bonding conditions being preferably set to 80° C. to 200° C., more preferably 140° C. as described above, the temperature under the second bonding conditions is preferably set to 100° C. to 200° C., more preferably 150° C., for example. Similar to the first bonding conditions, the application of ultrasonic waves under the second bonding conditions is not preferable. This is because stably applying ultrasonic vibration to individual first elements 10 is difficult in the case of bonding multiple first elements 10 to the wiring substrate 20 all at once and might result in bonding strength variation among the first elements 10.

In this embodiment, moreover, bonding under the second bonding conditions is performed multiple times. At least for two instances of bonding under the second bonding conditions, a different buffer sheet 103 or a different portion of the same buffer sheet 103 is used. This can enhance the bonding strength of the first bonding parts 11 to the second bonding parts 21, as well as reducing bonding strength variation among the first elements 10 to the wiring substrate 20.

The bonding step conducted in multiple instances will be more specifically described below.

As shown in steps S6 to S9 in FIG. 1, in this embodiment, the bonding conducted under the second bonding conditions (hereinafter “permanent bonding”) is repeated four times. The duration of each permanent bonding is set, for example, to four minutes. In other words, the permanent bonding is conducted for 16 minutes in total.

When conducting the permanent bonding for the first time, which is step S6 in FIG. 1, for example, the heights, obliqueness, or flatness of the light emission faces 13a of the first elements 10 vary as shown in FIG. 11. However, because the buffer sheet 103 plastically deforms in accordance with the shapes of the first elements 10, it comes into contact with the light emission faces 13a practically entirely. This can correct the warp, height variation, and obliqueness of the light emission faces 13a without destroying the first elements 10.

“Correcting” is not limited to cases in which the light emission faces 13a are made completely flat, the heights of the first elements 10 are made uniform, or the light emission faces 13a are made parallel to the upper face 22a of the base 22 completely. It is sufficient if the warp, height variation, or obliqueness of the light emission faces 13a is improved as compared to the state prior to being corrected. For example, after permanent bonding in the first instance, the warp, height variation, and obliqueness of the light emission faces 13a are reduced as compared to the provisionally bonded state.

As described above, immediately before permanent bonding in the first instance, because of the variation in the height, obliqueness, or flatness of the light emission faces 13a of the first elements 10, stress cannot be applied uniformly to the first elements 10 through the buffer sheet 103.

For example, in the case in which the heights of the light emission faces 13a of the first elements 10 vary, the stress applied via the buffer sheet 103 to the first elements 10 whose light emission faces 13a are relatively lower positioned is smaller than that applied to the first elements 13 whose light emission faces 13 are relatively higher positioned. In the case in which a light emission face 13a is oblique, the stress applied via the buffer sheet 103 to a portion of the light emission face 13a that is closer to the wiring substrate 20 is smaller than that applied to a portion of the light emission face 13a that is more distant from the wiring substrate 20. Furthermore, in the case in which a light emission face 13a is concave shaped, the stress applied via the buffer sheet 103 to the bottom portion of the curved face is smaller than that applied to the peripheral portion of the curved face. In the case in which a light emission face 13a is convex shaped, the stress applied via the buffer sheet 103 to the peripheral portion of the curved face is smaller than that applied to the top part of the curved face.

The portions of the first elements 10 subjected to smaller stress via the buffer sheet 103 have lower bonding strength between the first bonding parts 11 and the second bonding parts 21 than the portions subjected to larger stress. As a result, after completing permanent bonding at first instance, the bonding strength of the first elements 10 to the wiring substrate 20 greatly vary among the first elements.

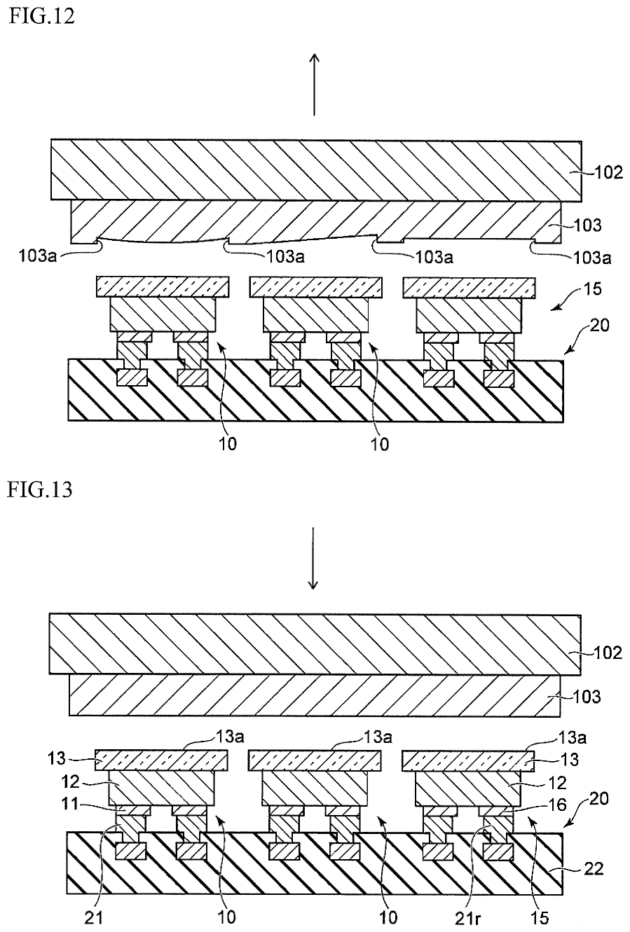

Next, as shown in FIG. 12, the press plate 102 and the buffer sheet 103 are detached from the first elements 10. Because the buffer sheet 103 plastically deforms when pushed onto the first elements 10, indentations 103a which reflect the shapes of the first element 10 are formed on the lower face of the buffer sheet 103.

Then in step S7 in FIG. 1, permanent bonding is conducted for the second time as shown in FIG. 13, for example. At this time, a new buffer sheet 103 or an unused portion of the buffer sheet 103 used in the permanent bonding at first instance is used. For this reason, no indentations 103a are present in the portion of the buffer sheet 103 that comes into contact with the first elements 10. The second bonding conditions are used in the permanent bonding at second instance. The bonding conditions for the permanent bonding at second instance can be changed from the second bonding conditions used in the permanent bonding at first instance.

Immediately before the permanent bonding at second instance, the height variation, the obliqueness, and the curves of the light emission faces 13a have been corrected. Furthermore, the buffer sheet 103 to be used has no indentations 103a. Accordingly, in the permanent bonding conducted in the second instance, stress is more uniformly applied to the first elements 10 via the buffer sheet 103 as compared to the permanent bonding conducted in the first instance.

As a result, the bonding strength variation of the first elements 10 to the wiring substrate 20 is reduced after the permanent bonding in the second instance as compared to the state immediately after the permanent bonding conducted in the first instance. Furthermore, the height variation, the obliqueness, and the curves of the light emission faces 13a which had not been corrected in the permanent bonding at first instance can be corrected in the permanent bonding at second instance.

Next, in step S8 in FIG. 1, permanent bonding is conducted for the third time. At this time, a new buffer sheet 103 or an unused portion of the buffer sheet 103 used in the permanent bonding at second instance is used. The second bonding conditions are used in the permanent bonding in the third instance. The bonding conditions for the permanent bonding at third instance can be changed from the second bonding conditions used in the permanent bonding at first or second instance.

This can more strongly bond the first bonding parts 11 and the second bonding parts 21. The bonding strength variation can also be reduced. Furthermore, the height variation, the obliqueness, and the curves of the light emission faces 13a which had not been corrected in the permanent bonding at first and second instances, if any, can be corrected in the permanent bonding at third instance.

Next, in step S9 in FIG. 1, permanent bonding is conducted for the fourth time. Similarly, a new buffer sheet 103 or an unused portion of the buffer sheet 103 used in the permanent bonding at third instance is used. The second bonding conditions are used in the permanent bonding at fourth instance, but the bonding conditions for the fourth time can be changed from the second bonding conditions used in the permanent bonding at first, second, or third instance. This can more strongly bond the first bonding parts 11 and the second bonding parts 21, further reducing the bonding strength variation.

The number of times the permanent bonding step is performed is not limited to four times. It has only to be performed multiple times, such as twice or more, and can be five times or more. Each time the permanent bonding step is conducted, a new buffer sheet 103 or a different portion of the previously used buffer sheet 103 is preferably used, but is not necessarily limited thereto. However, in at least two instances of permanent bonding, different buffer sheets 103 or different portions of the same buffer sheet 103 are preferably used.

Conducting the permanent bonding step multiple times as described above can integrate the first bonding parts 11 with the corresponding second bonding parts 21, creating fourth bonding parts 17. In the fourth bonding parts 17, most of the interfaces between the first bonding parts 11 and the second bonding parts 21 are eliminated. Furthermore, if air gaps existed at the interfaces, most of the air gaps are eliminated. This can achieve higher mechanical bonding strength between the first elements 10 and the wiring substrate 20 as compared to the provisionally bonded state. This state is referred to as “permanently bonded state.” A light emitting device 1 is manufactured by following the steps described above.

### Light Emitting Device

A light emitting device 1 thus manufactured will be explained next.

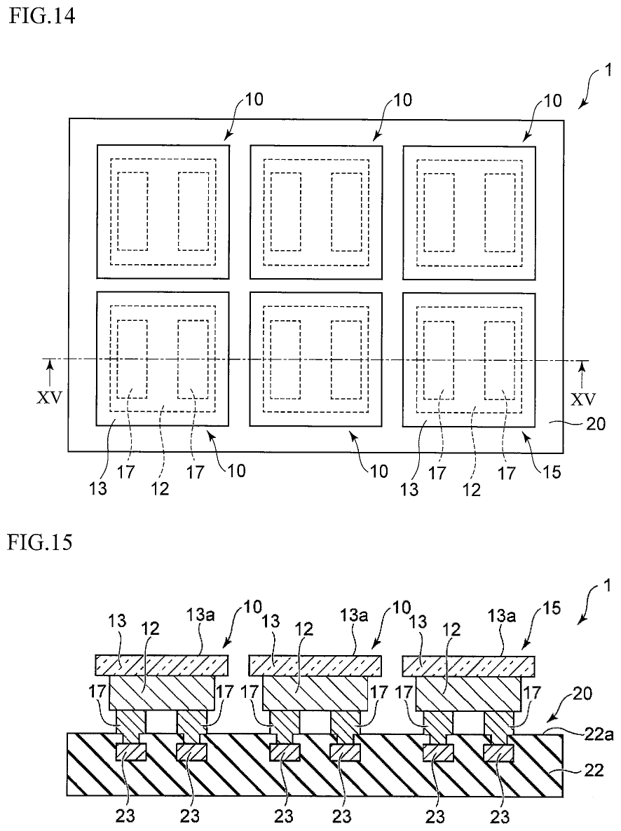

FIG. 14 is a plan view of a light emitting device according to this embodiment.

FIG. 15 is a cross-sectional view taken along line XV-XV in FIG. 14.

As shown in FIG. 14 and FIG. 15, a light emitting device 1 according to this embodiment has a wiring substrate 20, first elements 10, and fourth bonding parts 17. The first elements 10 include the second elements 15 described above. The number of first elements 10 is, for example, 10 or more. The first elements 10 are light emitting elements, for example, light emitting diodes. In a plan view, each first element 10 is quadrangular, for example, square.

Each first element 10 has a semiconductor member 12 and a wavelength conversion member 13 disposed on the semiconductor member 12. In the semiconductor member 12, a p-type semiconductor layer, an active layer, and a n-type semiconductor layer are stacked. In a plan view, the wavelength conversion member 13 is larger than the semiconductor member 12, and the outline of the wavelength conversion member 13 is located outside the outline of the semiconductor member 12. The wiring substrate 20 has an insulation base 22 and a number of conductive wires 23 disposed inside the base 22. The first elements 10 are arranged, for example, in a matrix on the upper face 22a of the wiring substrate 20.

The first elements 10 are electrically and mechanically connected to the wires 23 of the wiring substrate 20 via the fourth bonding parts 17. As described above, each fourth bonding part 17 is formed by integrating a first bonding part 11 and a second bonding part 21. Accordingly, the fourth bonding parts 17 include gold. For example, the fourth bonding parts 17 are entirely made of gold. In this embodiment, two fourth bonding parts 17 are bonded to each first element 10. One of the two fourth bonding parts 17 is connected to the p-type semiconductor layer of a first element 10, and the other is connected to the n-type semiconductor layer of the first element 10.

In a light emitting device 1, the bonding strength variation of the first elements 10 to the wiring substrate 20 is reduced. Moreover, the heights of the light emission faces 13a of the wavelength conversion members 13 from the wiring substrate 20 are practically uniform, and the light emission faces 13a are in parallel with the upper face 22a of the base 22 of the wiring substrate 20. In the present specification, being parallel has a tolerance of about a ±5° angle. The light emission faces 13a are practically flat.

The ratio (σ/A) of the standard deviation (σ) to the average value (A) of the bonding strength of the first elements 10 to the wiring substrate 20 is preferably 0.1 or lower, more preferably 0.03 or lower. Bonding strength refers to the magnitude of the force required to detach a first element 10 from the wiring substate 20 when the fore is applied to the first element 10 along the direction paralleling the upper face 22a of the base 22 of the wiring substrate 20. The average value and the standard deviation of the bonding strength are preferably calculated by measuring the bonding strength of all first elements 10 in a light emitting device 1. In the case in which ten or more first elements 10 are included in a light emitting device 1, they can be obtained by measuring the bonding strength of at least ten first elements 10.

Examples of the sizes and bonding strength of the light emitting device 1 will be explained.

In a first example, in a plan view, the length of each side of a first element 10, i.e., the length of each side of a wavelength conversion member 13 is 40 μm to 50 μm, for example, 45 μm. The distance between adjacent first elements 10 is 5 μm.

In a second example, in a plan view, the length of each side of a first element 10, i.e., the length of each side of a wavelength conversion member 13 is 500 μm to 1500 μm, for example, 1000 μm. The distance between adjacent first elements 10 is 50 μm to 150 μm, for example, 100 μm. In this case, the thickness of a fourth bonding part 17 is about 1 μm. The average value of the bonding strength of the first elements 10 to the wiring substrate 20 is 10 kgf or higher.

The effect of this embodiment will be explained below.

According to this embodiment, repeating the permanent bonding step multiple times as shown in steps S6 to S9 in FIG. 1 can apply a load to the first bonding parts 11 and the second bonding parts 12 while correcting the height variation, obliqueness, or curves of the light emission faces 13a even if the heights of the light emission faces 13a of the first elements 10 from the upper face 22a of the wiring substrate 20 varied, or the light emission faces are oblique or curved relative to the upper face 22a. Accordingly, a load can be uniformly applied to the first bonding parts 11 and the second bonding parts 12, thereby achieving a uniform bonding strength for the first elements 10 bonded to the wiring substrate 20. This, in other words, can achieve the ratio (σ/A) of the standard deviation (σ) to the average value (A) of the bonding strength of the first elements 10 to the wiring substrate 20 of 0.1 or lower, for example, 0.03 or lower, as described above.

In this embodiment, moreover, after provisionally bonding the first bonding parts 11 of the first elements 10 to the second bonding parts 21 of the wiring substrate 20 under the first bonding conditions in step S2 in FIG. 1, the electrical properties of the first elements 10 are evaluated in step S3 in FIG. 1 to allow for the removal in step S4 of any first element 10x that is determined to be unacceptable. Then in step S5, a second element 15 is placed in a region of the wiring substrate 20 from which a first element 10x has been removed. Then in the multiple instances of permanent bonding in steps S6 to S9, the first bonding parts 11 of the first elements 10 determined to be acceptable are bonded to the second bonding parts 21 as well as bonding any newly placed second element 15 to the second bonding parts 21r which used to be bonded to an unacceptable first element 10x.

This can provisionally bond the first elements 10 to the wiring substrate 20 all at once to evaluate the electrical properties of the first elements 10 via the wiring substrate 20. Furthermore, an unacceptable first element 10x can be efficiently replaced with a second element 15. This, as a result, can improve the production efficiency for the light emitting device 1.

Furthermore, in this embodiment, provisional bonding is conducted under the first bonding conditions, and permanent bonding is conducted under the second bonding conditions. The second bonding conditions achieve a higher bonding strength than the first bonding conditions. Accordingly, in the provisional bonding step under the first bonding conditions, the first bonding parts 11 are connected to the second bonding parts 21, but have a lower mechanical bonding strength than that in the permanently bonded state. This makes it easier to remove any first element 10x determined to be unacceptable when the electrical properties of the first elements 10 are evaluated. In the permanent bonding step conducted under the second bonding conditions, the bonding strength of the first bonding parts 11 to the second bonding parts 21 is higher than that in the provisionally bonded state. This can enhance the bonding strength between the first elements 10 and the wiring substrate 20, thereby improving the reliability of the light emitting device 1.

In this embodiment, furthermore, a laser beam 104 is irradiated on a first element 10x determined to be unacceptable to heat the first element 10x and generate thermal stress between the first bonding parts 11 of the first element 10x and the second bonding parts 21r. This can disjoin the first bonding parts 11 and the second bonding parts 21r while reducing the damage to the wiring substrate 20. Moreover, irradiating a laser beam 104 only on a first element 10x allows for high precision heating of the unacceptable first element 10x among multiple first elements 10.

In this embodiment, furthermore, the first bonding parts 11, the second bonding parts 21, and the third bonding parts 16 include gold. In the provisional bonding step, the gold-containing portion of a first bonding part 11 is connected to the gold-containing portion of a second bonding part 21. For example, the outermost surface, which is made of gold, of a first bonding part 11 is connected to the outermost surface, which is made of gold, of a second bonding part 21. Subsequently, a first element 10x determined to be unacceptable is removed by generating thermal stress at the bonding interfaces between the first bonding parts 11 of the first element 10x and the second bonding parts 21.

In comparison, for example, the first bonding parts 11 can be provisionally bonded to the second bonding parts 21 by using a bonding material containing tin (Sn). However, it is difficult to remove a tin-containing bonding material once bonded. Thus, residues of the bonding material might remain on the surfaces of the second bonding parts 21r after removing a first element 10x. The residues of the bonding material might reduce the bonding strength of the third bonding parts 16 of a second element 15 to the second bonding parts 21r.

In this embodiment, because the first bonding parts 11 and the second bonding parts 21 are disjoined at the interfaces of the portions that contain gold in the step of removing a first element 10x, residues barely remain on the surfaces of the second bonding parts 21r. This can enhance the bonding strength of the third bonding parts 16 of a second element 15 to the second bonding parts 21r.

In this embodiment, moreover, the electrical properties of a second element 15 can be evaluated via the wiring substrate 20 after bringing the third bonding parts 16 of the second element 15 into contact with the second bonding parts 21r of the wiring substrate 20. If the second element 15 is determined to be unacceptable in this step, the second element 15 can be removed using a similar method to that used to remove a first element 10x. At this time, before evaluating the electrical properties, the third bonding parts 16 can be connected under the first bonding conditions to be provisionally bonded to the second bonding parts 21r.

In this embodiment, an example in which each first element 10 has a wavelength conversion member 13 has been described, but the first elements 10 do not have to have a wavelength conversion member. In this embodiment, furthermore, an example in which the first elements 10 are light emitting elements has been described, but the invention is not limited to this. For example, the first elements can be arithmetic elements, memory elements for storing data, or power control switching elements.

### Second Embodiment

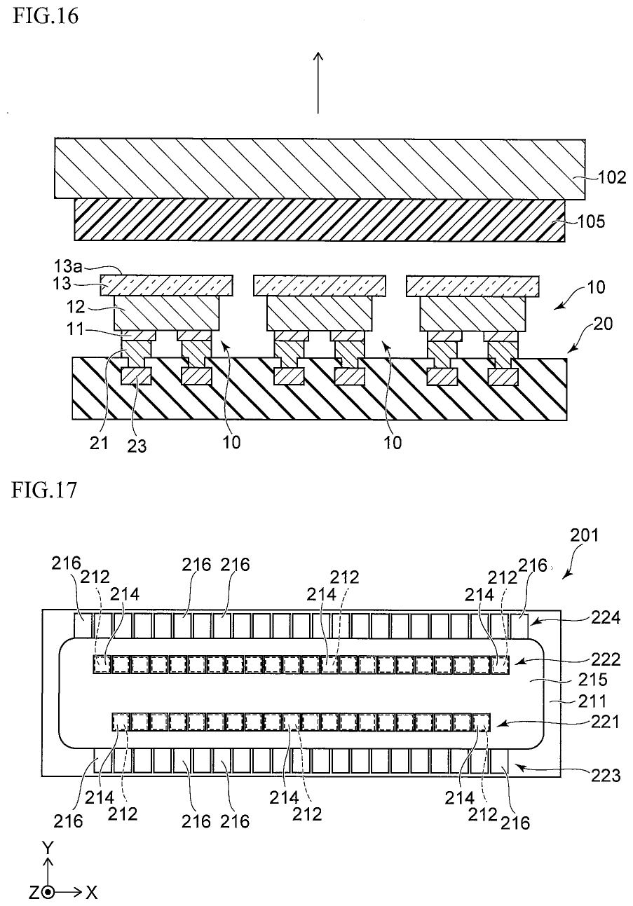

FIG. 16 is a cross-sectional view showing a method of manufacturing a light emitting device according to a second embodiment.

FIG. 16 corresponds to FIG. 12 of the first embodiment, showing the state between first two instances of permanent bonding.

As shown in FIG. 16, this embodiment differs from the first embodiment such that a flexibly deformable buffer sheet 105 is used instead of a plastically deformable buffer sheet 103, and the same portion of the same buffer sheet 105 is used during at least two instances of permanent bonding. The flexibly deformable buffer sheet 105 is, for example, a sheet made of silicone rubber, and has a thickness of 0.1 mm to 0.2 mm, for example, 0.1 mm.

In this embodiment, because a flexibly deformable sheet is used as the buffer sheet 105, no indentation reflecting the shapes of the first elements 10 are formed on the buffer sheet subsequent to the permanent bonding step. For this reason, even when the same portion of the same buffer sheet 105 is used in the subsequent instances of permanent bonding, a load can be applied uniformly to the first elements 10. The methods, constituents, and effect of this embodiment other than those described above are similar to those in the first embodiment. Similar to the first embodiment, a different buffer sheet 105 or a different portion of the same buffer sheet 105 can be used in at least two instances of permanent bonding in this embodiment.

### Third Embodiment

A third embodiment is an example of manufacturing a light emitting module by using a method of manufacturing a light emitting device according to the first embodiment described earlier.

The constituents of a light emitting module according to this embodiment will be explained first.

FIG. 17 is a plan view of a light emitting module according to this embodiment.

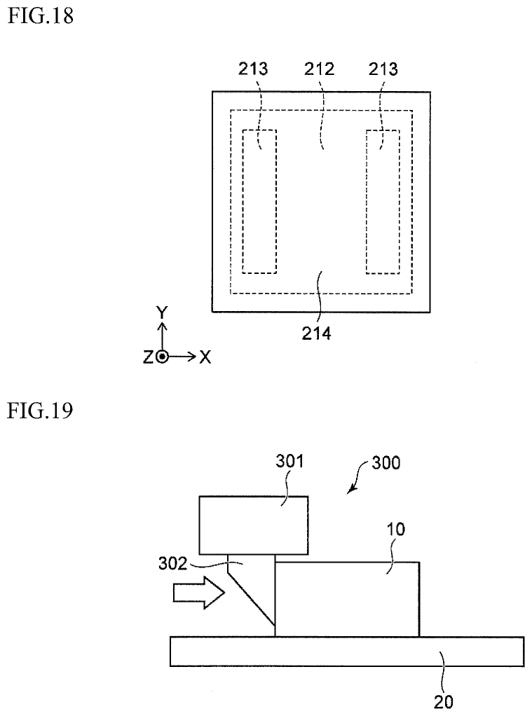

FIG. 18 is a plan view partially enlarging a first element and a wavelength conversion member in this embodiment.

As shown in FIG. 17 and FIG. 18, a light emitting module 201 according to this embodiment includes a wiring substrate 211. The plan view shape of the wiring substrate 211 is, for example, rectangular. A number of first elements 212 are arranged on the upper face of the wiring substrate 211. Each first element 212 has two bonding parts 213, and is placed on the wiring substrate 211 via the bonding parts 213. The bonding parts 213 include gold.

For the purpose of explaining this embodiment, an XYZ orthogonal coordinate system will be employed. The lengthwise direction of the wiring substrate 211 is “X direction,” the widthwise direction is “Y direction,” and the thickness direction is “Z direction.” The Z direction from the wiring substrate 211 towards the first elements 212 is also referred to as the “upward” direction and the opposite direction the “downward” direction, but these expressions are also used as a matter of convenience and are unrelated to the direction of gravity.

On the upper face of the wiring substrate 211, the first elements 212 are arranged in two rows, for example. Each row extends in the lengthwise direction of the wiring substrate 211, i.e., the X direction. In the first row 221, twenty first elements 212 are arranged, for example, and in the second row 222, twenty-two first elements 212 are arranged, for example. Accordingly, a total of 42 first elements 212 are arranged in the light emitting module 201. In one example, a plan view shape of a first element 212 is a square, each side being 500 μm to 1000 μm in length.

On each first element 212, a wavelength conversion member 214 is disposed. The wavelength conversion member 214 is a sheet shaped member that contains YAG as a phosphor, for example. In one example, the plan view shape of each wavelength conversion member 214 is a square, each side being 550 μm to 1100 μm in length. The distance between adjacent wavelength conversion members 214 in each row is 30 μm to 70 μm in one example. The number of wavelength conversion members 214 is the same as the number of the first elements 212.

A resin member 215 is disposed on the wiring substrate 211. The resin member 215 covers the central portion of the upper face of the wiring substrate 211. The resin member 215 covers the lateral faces of the first elements 212 and the lateral faces of the wavelength conversion members 214, but does not cover the upper faces of the wavelength conversion members 214. Accordingly, the upper faces of the wavelength conversion members 214 are exposed from the resin member 215. The resin member 215 is, for example, a light transmissive resin which contains a light reflecting substance. The resin is, for example, a silicone resin. The light reflecting substance is, for example, titanium oxide.

Pads 216 are arranged on the upper face of the wiring substrate 211 at both ends in the Y direction of the region covered by the resin member 215. The pads 216 are arranged in two rows extending in the X direction along the edges of the wiring substrate 211. The pads 216 in the third row 223 are located along the edge near the first row 221 of the first elements 212. The pads 216 in the fourth row 224 are located along the edge near the second row 222 of the first elements 212.

The number of pads 216 in each row is greater than the number of the first elements 212 in the corresponding row by one. In other words, the third row 223 has twenty-one pads 216, and the fourth row 224 has twenty-three pads 216. The twenty-one pads 216 in the third row and the twenty first elements 212 in the first row are alternately connected in series. Similarly, the twenty-three pads 216 in the fourth row and the twenty-two first elements 212 are alternately connected in series.

A method of manufacturing a light emitting module according to this embodiment will be explained next.

A wiring substrate 211 is prepared as shown in FIG. 17. Pads 216 are arranged on the upper face of the wiring substrate 211. The wiring substrate 211 of this embodiment corresponds to the wiring substrate 20 of the first embodiment. Then on the wiring substrate 211, first elements 212 are placed. The first elements 212 of this embodiment correspond to the first elements 10 of the first embodiment excluding the wavelength conversion members 13.

At this time, as described with reference to the first embodiment, the first elements 212 are provisionally bonded to the wiring substrate 211, the electrical properties such as the luminous intensity of the first elements 212 are evaluated, and the first elements 212 determined to be unacceptable are removed. Then a new first element 212 is placed in the region from which an unacceptable element has been removed, and all first elements 212 are permanently bonded at once. A new first element 212 in this embodiment corresponds to a second element 15 in the first embodiment. An unacceptable first element 212 is thus replaced with an acceptable element. Bonding parts 213 are formed between the wiring substrate 211 and the first elements 212. The bonding parts 213 correspond to the fourth bonding parts 17 in the first embodiment.

Similar to the first embodiment, the permanent bonding step is performed multiple times. In each instance of permanent bonding, a plastically deformable buffer sheet 103 is used. At least twice, every time, if possible, a different buffer sheet 103 is used, or a different portion of the same buffer sheet 103 is used. Similar to the second embodiment, by using a flexibly deformable buffer sheet 105, the same portion of the same buffer sheet 105 can be used in the multiple instances of permanent bonding.

Then a wavelength conversion member 214 is placed on each first element 212. The wavelength conversion members 214 in this embodiment correspond to the wavelength conversion members 13 in the first embodiment. Then a resin member 215 is formed to cover the upper face of the wiring substrate 211, the lateral faces of the first elements 212, and the lateral faces of the wavelength conversion members 214. In this manner, a light emitting module 201 according to this embodiment is manufactured.

The ratio of the standard deviation to the average value of the bonding strength of the first elements 212 to the wiring board 211 is preferably 0.1 or lower, more preferably 0.03 or lower. The average bonding strength is preferably 10 kgf or higher.

The embodiments described above are specific examples of the present invention, and the present invention is not limited to these embodiments. For example, any form achieved by adding or deleting certain constituents or steps of any of the embodiments described above is encompassed by the present invention.

### Test Example

A test example demonstrating the effect of the first embodiment will be explained next.

FIG. 19 is a diagram of a measuring device for measuring the bonding strength of the test example.

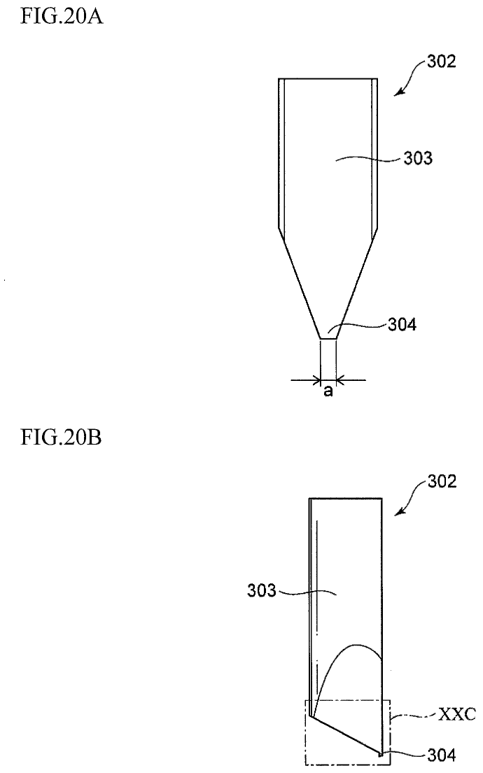

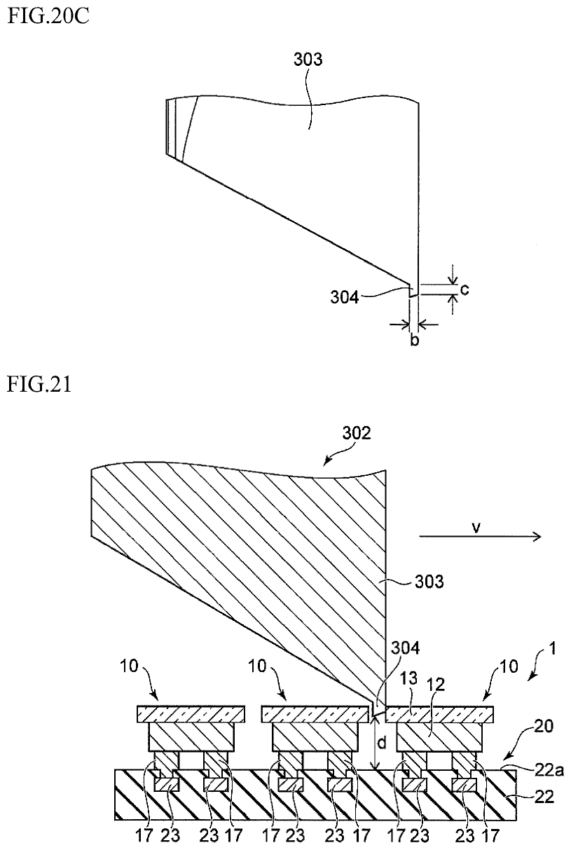

FIG. 20A is a front view of the tool portion of the measuring device used to measure the test example. FIG. 20B is a side view of the same, and FIG. 20C is a side view enlarging the region XXC in FIG. 20B.

FIG. 21 is a cross-sectional view showing a method of measuring the bonding strength of the test example.

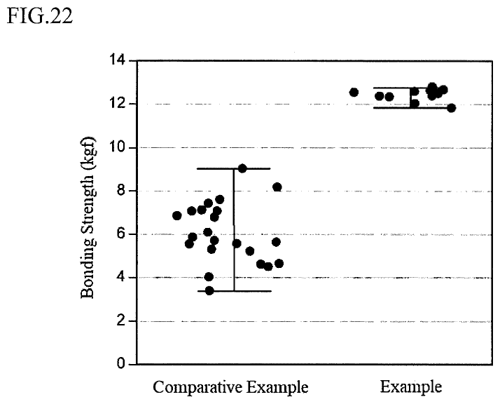

FIG. 22 is a graph showing the bonding strength of the test example and a comparative example. The horizontal axis of the graph represents the example type, and the vertical axis represents the bonding strength of the first elements to the wiring substrate, showing the effect of repeated permanent bonding.

As shown in FIG. 19, the bonding strength measuring device 300 has a load sensor 301 and a tool 302 attached to the load sensor 301.

As shown in FIG. 20A to FIG. 20C, the tool 302 has a main body 303 and a tip 304 which are integrally formed. The tool 302 is made of cemented carbide. The shape of the main body 303 is practically cylindrical. The upper portion of the main body 303 is uniform in size, and in the lower portion, the size decreases towards the lower end. The tip 304 extends from the lower end of the main body 303. The tip 304 is sheet-shaped. The width a of the tip 304 is about 1 mm, the thickness b about 0.2 mm, and the height c about 0.2 mm.

For the test example, as an example of the present invention, a sample was prepared by conducting the permanent bonding step as described with reference to the first embodiment. The bonding was repeated four times, and the bonding duration was 4 minutes each time. In other words, the total bonding time was 16 minutes. For the buffer sheet 103, a carbon sheet which was 0.13 mm in thickness was used. As a comparative example, a sample was prepared by conducting the permanent bonding step only once. The bonding duration was 15 minutes. The temperature used in both the example and the comparative example was 200° C., and the load applied was 44 MPa.

As shown in FIG. 21, the tip 304 of the tool 302 of the measuring device 300 was inserted between two first elements 10 to oppose the lateral face of the wavelength conversion member 13 of one of the first elements 10. At this time, the clearance d between the wiring substrate 20 and the tool 302 was 30 μm. Then the measuring device 300 was moved along the direction paralleling the upper face 22a of the wiring substrate 20. The moving speed v was 100 μm/s. By moving the measuring device 300, the tip 304 of the tool 302 was abutted against the lateral face of the wavelength conversion member 13 and a force was applied to the first element 10. The load sensor 301 measured the load at which the first element 10 became detached from the wiring substrate 20, which was used as the bonding strength.

For the example, the bonding strength of twelve first elements 10 were measured. For the comparative example, the bonding strength of twenty-four first elements 10 were measured. The measurements are plotted in FIG. 22. Table 1 shows the average value (A), the maximum value (Max), the minimum value (Min), the standard deviation (σ), and the ratio of the standard deviation to the average (σ/A) for the example and the comparative example.

TABLE 1

| | Example | Comparative Example |
|---|---|---|
| Average Value (A) (kgf) | 12.43 | 6.01 |
| Maximum Value (Max) (kgf) | 12.80 | 9.01 |
| Minimum Value (Min) (kgf) | 11.83 | 3.40 |
| Standard Deviation (σ) (kgf) | 0.26 | 1.33 |
| Ratio (σ/A) | 0.02 | 0.22 |

As shown in Table 1 and FIG. 22, the bonding strength of the example was high, the average bonding strength of the example being 12.43 kgf as compared to 6.01 kgf for the comparative example. The example had smaller variation as shown by the ratio of the standard deviation to the average (σ/A) of 0.02 as compared to 0.22 for the comparative example.

An embodiment of the present invention can be utilized, for example, as an automotive headlight, a light source of a display device, and the like.

1. A method of manufacturing a light emitting device comprising:
preparing a plurality of first elements and a wiring substrate, the plurality of first elements includes first bonding parts, the wiring substrate includes a plurality of second bonding parts;
placing the plurality of first elements on the wiring substrate by bonding the first bonding parts and the second bonding parts under first bonding conditions; and
bonding the first bonding parts and the second bonding parts under second bonding conditions by placing a buffer sheet on the plurality of first elements and applying pressure on the plurality of first elements via the buffer sheet towards the wiring substrate,
the bonding conducted under the second bonding conditions being performed multiple times.

2. The method of manufacturing a light emitting device according to claim 1, further comprising, subsequent to placing the plurality of first elements on the wiring substrate and before conducting bonding under the second bonding conditions:
evaluating the electrical properties of the plurality of first elements;
removing any first element of the plurality of first elements that is determined to be unacceptable in the evaluation of the electrical properties from the wiring substrate by detaching the first bonding parts of the first element determined to be unacceptable from the second bonding parts; and
placing a second element including third bonding parts in a region of the wiring substrate in which a removed first element used to be placed and bringing the third bonding parts into contact with the second bonding parts which used to be bonded to the first bonding parts of the removed first element,
the third bonding parts being bonded to the second bonding parts which used to be bonded to the first bonding parts of the removed first element in the bonding under the second bonding conditions.

3. The method of manufacturing a light emitting device according to claim 1, wherein
the buffer sheet is a plastically deformable sheet, and
in at least two instances of the bonding conducted under the second bonding conditions, a different buffer sheet or a different portion of the same buffer sheet is used.

4. The method of manufacturing a light emitting device according to claim 1, wherein
the buffer sheet is a flexibly deformable sheet, and
in at least two instances of the bonding conducted under the second bonding conditions, the same buffer sheet is used.

5. The method of manufacturing a light emitting device according to claim 1, wherein a load of the applied pressure in the second bonding conditions is higher than a load of an applied pressure in the first bonding conditions.

6. The method of manufacturing a light emitting device according to claim 1, wherein a load of an applied pressure applied to the first bonding parts and the second bonding parts under the first bonding conditions is 10 MPa to 100 MPa, and a load of the applied pressure applied to the first bonding parts and the second bonding parts under the second bonding conditions is 10 MPa to 440 MPa.

7. The method of manufacturing a light emitting device according to claim 1, wherein a duration in which a load of the applied pressure is applied to the first bonding parts and the second bonding parts under the second bonding conditions is longer than a duration in which a load of an applied pressure is applied to the first bonding parts and the second bonding parts under the first bonding conditions.

8. The method of manufacturing a light emitting device according to claim 1, wherein a duration in which a load of an applied pressure is applied to the first bonding parts and the second bonding parts under the first bonding conditions is 0.1 seconds to 10 seconds, and a duration in which a load of the applied pressure is applied to the first bonding parts and the second bonding parts under the second bonding conditions is 1 minute to 10 minutes.

9. The method of manufacturing a light emitting device according to claim 1, wherein the temperature in the second bonding conditions is 100° C. to 200° C.

10. The method of manufacturing a light emitting device according to claim 1, wherein each first element of the plurality of first elements includes a semiconductor member, first bonding parts disposed on a first face of the semiconductor member, and a wavelength conversion member disposed on a second face of the semiconductor member located opposite the first face.

11. The method of manufacturing a light emitting device according to claim 1, wherein the first bonding parts and the second bonding parts include gold.

12. A light emitting device comprising:
a wiring substrate having wires;
a plurality of first elements; and
a plurality of bonding parts for connecting the plurality of first elements to the wires, wherein
a ratio of a standard deviation to an average value of a bonding strength of the plurality of first elements to the wiring substrate is 0.1 or lower.

13. The light emitting device according to claim 12, wherein the ratio is 0.03 or less.

14. A light emitting device comprising:
a wiring substrate having wires;
a plurality of first elements; and
a plurality of bonding parts for connecting the plurality of first elements to the wires, wherein
a length of a side of each first element of the plurality of first elements in a plan view is 500 μm to 1500 μm, and
an average value of a bonding strength of the plurality of first elements to the wiring substrate is 10 kgf or higher.

15. The light emitting device according to claim 14, wherein a ratio of a standard deviation to the average value of the bonding strength of the plurality of first elements to the wiring substrate is 0.1 or lower.
